(19) United States
(12) Patent Application Publication
(10) Pub. No.: US 2019/0157483 A1
(43) Pub. Date: May 23, 2019

(54) Solar cell module configuration and printed circuit board substrate for solar cell modules

(71) Applicant: Raja Singh Tuli, Montreal (CA)

(72) Inventor: Raja Singh Tuli, Montreal (CA)

(21) Appl. No.: 15/818,676

(22) Filed: Nov. 20, 2017

(51) Int. Cl. H01L 31/05; H01L 31/02; H01L 31/054

(52) U.S. Cl. CPC H01L 31/0504; H01L 31/0547; H01L 31/02008

(57) ABSTRACT

The present invention discloses a solar module, preferably for use within a solar energy concentrator system. The solar module comprises multiple solar cells that are divided into sets. The solar cells constituting a set form a parallel circuit, while the sets are connected together in series. The sets are arranged such that they each generate substantially the same amount of current despite solar cells potentially receiving an uneven diffusion of solar radiation. The voltage of each set can thus be added together without yielding any significant efficiency loss. In a further embodiment, electrical contacts and conductors with relatively high resistance on the solar cells are located on their back sides, coupled to conductors with relatively low resistance on a PC board substrate incorporated as a substrate to the solar module. This circuit reduces the overall resistance of the circuit, especially when integrated to a solar energy concentrator system.

### BACKGROUND OF THE INVENTION

### Field of the Invention

The present invention generally relates to photovoltaic devices, particularly for solar modules integrated in solar energy concentrator systems. More specifically, the principal embodiment of the present invention relates to the internal electrical circuitry connecting solar cells in a solar module.

### Description of the Related Art

With the worldwide population growing steadily, demand for energy scales up. This intensifying demand takes place in a time when traditional sources of energy face particular pressure due to the scarcity of resources as well as stronger calls by customers and households for energy sources that minimize the negative environmental impact. To help solve this problem, solar energy constitutes an attractive and reliable alternative based on a readily available energy source—solar light. In this context, there is a need for a better use of solar energy, more specifically, for means that provide a better collection of concentrated solar radiation.

A solar cell is typically made of semiconductor materials, such as silica, with at least one layer of positively charged materials and one layer of negatively charged materials together creating an electric field. When solar radiation impinges on a solar cell, electrons are knocked off and wander around in accordance with the electric field. If the layer of positively charged materials is paired with the layer of negatively charged materials through a conductive component, the electrons that are knocked off will rather move to and through this conductor, thereby forming an electrical circuit. Electrons traveling through this conductor can be used as electrical energy by external applications, before returning to the solar cell. A plurality of solar cells can be grouped together as a solar panel or module in order to cover a larger area and, this way, generate more electrical current or power, or more of both.

When a solar module is oriented toward the sun without obstacles, the solar radiation impinging on the solar module is uniform throughout the surface of the solar module. With this orientation, each solar cell constituting the solar module receives the same amount of radiation. As a result, each of these solar cells generates more or less the same current intensity. When connecting these solar cells in series, their voltage is added, while the current that is generated is equal to the lowest current generated by any of the solar cells. Consequently, because solar cells receiving uniform solar radiation generate more or less the same current intensity, they can be connected in series to increase the voltage output of the module without substantial loss in current intensity.

In a solar energy concentrator system, the solar module is rather oriented toward a concentrator, which typically redirects solar radiation unevenly. Because of this uneven diffusion, there is a significant difference between the current intensity produced by each of the solar cells constituting the solar module. Should the solar cells of the solar module be connected in series, the resulting current intensity of the solar module would be equal to the least-performing of the solar cells, despite the fact that some of those solar cells generate more current. This loss is significant, affecting the technical performance of solar energy concentrator systems as well as their cost-efficiency. Should the solar cells in a solar energy concentrator system be connected in parallel instead, the voltage that would be generated might be too low for the current to flow smoothly through the circuit's resistance. An energy-intensive convertor, a charge pump or an equivalent device would be required to increase the voltage, thereby negatively affecting the overall performance and cost-efficiency of the system.

The present invention implements a particular configuration of solar cells and circuitry that, when integrated into a solar energy concentrator system, circumvent the problems described above. Despite being particularly beneficial when integrated to a solar energy concentrator system, it can function in combination with non-concentrating solar energy systems. Solar energy concentrator systems offer various benefits over non-concentrating solar energy systems: for an equivalent electrical output, significantly less resources and space are required to operate a solar energy concentrator system. However, the operation of solar energy concentrator systems with solar modules involves particular inefficiency factors such as the uneven diffusion of solar light, heat and electrical resistance. These factors must be addressed in an efficient solar energy concentrator system.

### SUMMARY OF THE INVENTION

In a solar module characterized by the principal embodiment of the present invention, a very high number of solar cells are assembled together. The solar cells are distributed into multiple sets, each of these sets containing a certain number of solar cells. In a two-part electrical circuit, solar cells within each set form a parallel circuit, while the sets are connected together in series. Preferably, the solar module comprises a large number of sets, and each set connects numerous solar cells together.

The solar cells that constitute a set are determined with a particular configuration by which the current intensity generated by each of the sets is more or less the same. In the second stage of the electrical circuit, the sets are connected together in series, thereby increasing the voltage of the electrical circuit of the solar module. Since sets are determined such that the current intensity of each set is relatively the same to one another, current intensity inefficiencies in the second stage of the electrical circuit are small or minimal.

In the principal embodiment of the present invention, the solar cells constituting each of the sets are numerous and randomly selected. With these set selection characteristics, it is very probable statistically that the current intensity generated by each of the sets is more or less the same. Since the current intensity of each set is very likely to be similar to one another, the probability of current intensity inefficiencies in the second stage of the electrical circuit is small.

In a first alternate embodiment, the solar cells constituting each of the sets are not selected randomly but instead determined on the basis of prior simulations or calculations maximizing the current output of the set that produces the least current. Calculations yielding this result are known as “minimax”. The simulations or calculations can also be achieved during operation, with the sets being mechanically or electronically re-configured mid-operation. In this first alternate embodiment, the two-stage electrical circuitry within and between the sets is the same as in the principal embodiment.

In a second alternate embodiment, the solar cells constituting each of the sets are selected radially instead of being randomly determined. In this configuration, each set of the solar module follows a radial pattern, diverging in line from the center of the solar module. A solar energy concentrating system can be operated in a way that aligns the center of the solar module with the center of the target area of redirected solar radiation. In these circumstances, the current intensity of the various sets designed radially is very likely to be roughly the same. In this second alternate embodiment, the two-stage electrical circuitry within and between the sets is the same as in the principal embodiment.

In a third alternate embodiment, the solar cells constituting each of the sets are selected circularly instead of being randomly determined. In this configuration, each set of the solar module follows a roughly circular, oval, spiral or helical pattern designed around the center of the solar module. Preferably, the solar cells constituting each set are not adjacent to one another. As the solar cells constituting each set are widely distributed across the surface of the solar module when they are not adjacent, the expected output obtained with this embodiment can be somewhat similar to the expected output of the principal embodiment whereby sets are determined randomly. In this third alternate embodiment, the two-stage electrical circuitry within and between the sets is the same as in the principal embodiment.

In a fourth alternate embodiment, the solar cells constituting each of the sets are selected linearly instead of being randomly determined. In this configuration, each set of the solar module follows a roughly linear pattern passing by or near the center of the solar module. Preferably, the solar cells constituting each set are not adjacent to one another. A solar energy concentrating system can be operated in a way that aligns the center of the solar module with the center of the target area of redirected solar radiation. In these circumstances, the current intensity of the various sets designed linearly is very likely to be roughly the same. In this fourth alternate embodiment, the two-stage electrical circuitry within and between the sets is the same as in the principal embodiment.

In a fifth alternate embodiment, the solar module is constituted of many sub-modules. In this embodiment, the solar cells constituting each of the sets are selected on the basis of their position in each sub-module instead of being randomly determined. As the solar cells constituting each set are widely distributed across the surface of the solar module, the expected output obtained with this embodiment can be somewhat similar to the expected output of the principal embodiment whereby sets are determined randomly. In this fifth alternate embodiment, the two-stage electrical circuitry within and between the sets is the same as in the principal embodiment.

In an additional embodiment of the present invention, the resistance of the circuit is significantly reduced even when the solar cell receives concentrated solar radiation up to thirty suns or more, thus allowing a high output of electrical conversion. In this additional embodiment, solar cells are connected together to form an electrical circuit. The solar cells can be standard solar cells so long as they are designed in a way that their electrical contacts and other conductive elements are positioned on their back sides, whereon conductors with relatively high resistance are located. The solar cells are installed on a printed circuit board or any other equivalent support. The printed circuit board comprises a substrate and conductors with relatively low resistance, which are typically thicker or wider (or both) than the conductors with relatively high resistance on the solar cells. The conductors with relatively high resistance on the solar are coupled to the conductors with relatively low resistance on the printed circuit board through one of various means, for instance, solder balls. The solar cells are connected to the printed circuit board through the solder balls and, both ends of the solder balls are respectively aligned with the conductors with relatively high resistance on the solar cells and the conductors with relatively low resistance on the printed circuit board. Therefore, the conductors with relatively low resistance on the printed circuit board are aligned with the conductors with relatively high resistance on the solar cells in a design that reduces the resistance of the overall electrical circuit.

### BRIEF DESCRIPTION OF THE SEVERAL VIEWS OF THE DRAWINGS

The invention is described in more detail below with respect to an illustrative embodiment shown in the accompanying drawings in which:

FIG. 1 is a drawing illustrating a perspective view of a solar energy concentrator system.

FIG. 2 is a drawing illustrating a plan view of an example of uneven solar radiation received by a solar module integrated to a solar energy concentrator system.

FIG. 3 is a drawing illustrating a plan view of an exemplary solar module in accordance with the principal embodiment of the present invention.

FIG. 4 is a drawing illustrating a plan view of a randomly-determined set of solar cells in accordance with the principal embodiment of the present invention.

FIG. 5 is a drawing illustrating a plan view of a radially-designed set of solar cells in accordance with the second alternate embodiment of the present invention.

FIG. 6 is a drawing illustrating a plan view of a circularly-designed set of solar cells in accordance with the third alternate embodiment of the present invention.

FIG. 7 is a drawing illustrating a plan view of a linearly-designed set of solar cells in accordance with the fourth alternate embodiment of the present invention.

FIG. 8 is a drawing illustrating a plan view of a sub-module position-based set of solar cells in accordance with the fifth alternate embodiment of the present invention.

FIG. 9 is a drawing illustrating a sectional view from a side angle of an exemplary solar module whereby solar cells are installed on a printed circuit board in accordance with the additional embodiment of the present invention.

FIG. 10 is a drawing illustrating a sectional view from a bottom angle of an exemplary solar cell installed on a printed circuit board in accordance with the additional embodiment of the present invention.

FIG. 11 is a drawing illustrating a sectional view from a top angle of an exemplary solar cell installed on a printed circuit board in accordance with the additional embodiment of the present invention.

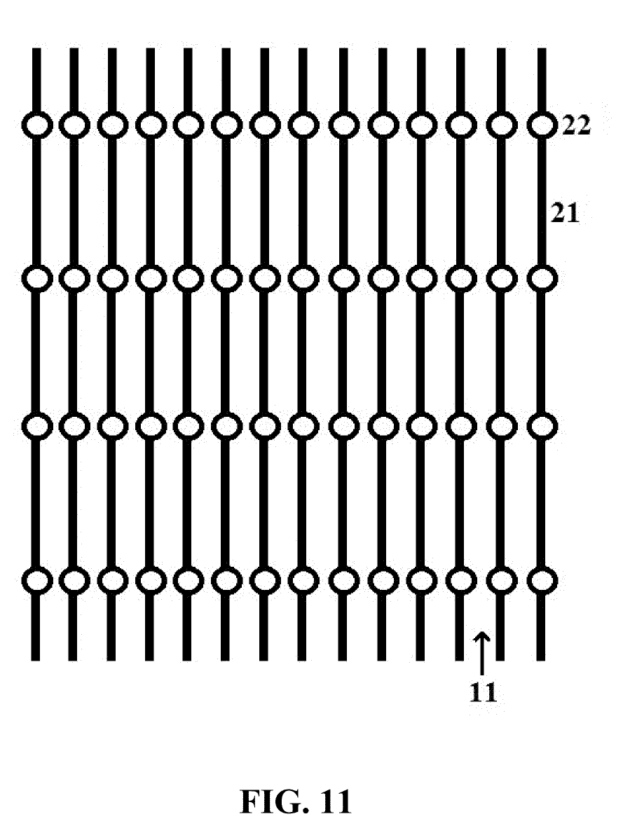

The components in the figures are not necessarily drawn to scale. Where used in the various figures of the drawings, the same numerals designate the same or similar parts.

### DETAILED DESCRIPTION OF THE INVENTION

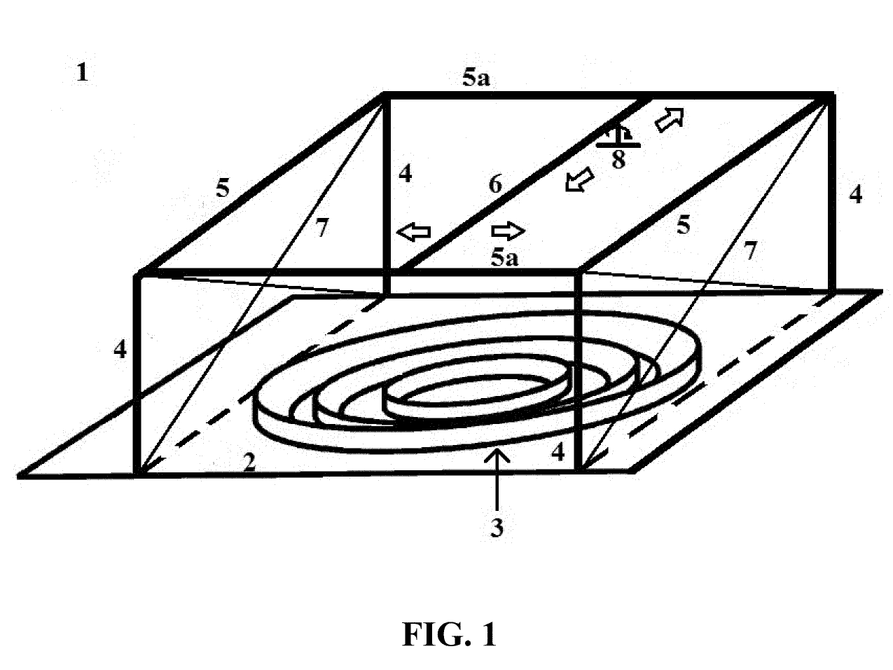

For reference purposes only, the present invention is disclosed as being integrated into a solar energy concentrating system. A person skilled in the art would recognize that the present invention can be integrated to many other concentrating and non-concentrating solar energy systems. An example of a solar energy concentrating system 1 is illustrated in FIG. 1. In that example, a structure is erected on the stationary plane of a concentrating reflector 2 made of an array of reflecting surfaces 3 laid over a two-dimensional, stationary plane surface on which they are themselves stationary. The structure is constituted of four vertical beams 4. Equal in number to the vertical beams 4, lateral beams 5, 5a connect the vertical beams 4 together, preferably at their top ends. A lateral arm 6 is connected to any two lateral beams 5a facing each other. To strengthen and stabilize the structure and the lateral arm 6, support cables 7 can be added to the structure. When solar rays impinge on the reflecting surfaces 3, each of them redirects the light toward one common small target area, just like in a Fresnel lens, thus focusing solar radiation at this focal area. Since the reflecting surfaces 3 are stationary, this target area continually changes position based on daily and seasonal solar movement in the sky.

In that example of a solar energy concentrating system 1, the lateral arm 6 supports a solar module 8 that can be attached or connected to the lateral arm 6 in various ways. A motorized system inside the lateral arm 6 allows the solar module 8 to move along the lateral arm 6. In addition, a motorized system inside the two lateral beams 5a that support the lateral arm 6 allows the lateral arm 6 to be moved along the entire lengths of the two lateral beams 5a to which the lateral arm 6 is connected. The solar module 8 is installed in a way that allows its rotation. With the rotation of the solar module 8, the movement of the solar module 8 along the lateral arm 6, and the movement of the lateral arm 6 along the two lateral beams 5a to which the lateral arm 6 is connected, the structure is capable of moving the solar module 8 at or near any location of the focal area of concentrated solar radiation. A mirror reflector 9 can be fastened against the solar module 8. If there is solar radiation that is redirected by the concentrating reflector 2 and whose trajectory does not meet the space covered by the solar module 8, the mirror reflector 9 potentially diverts some of it toward the solar module 8.

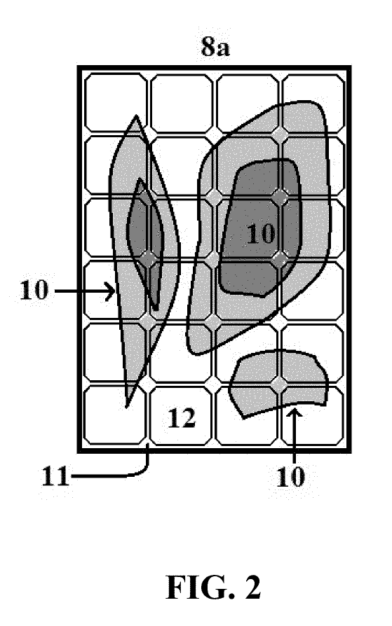

FIG. 2 illustrates an example of the resulting sunlight diffusion 10 should it be received at a given moment by a standard photovoltaic solar module 8a. For illustrative purposes, this standard photovoltaic solar module 8a is constituted of a substrate 11 whereon solar cells 12 are affixed and linked in a series electrical circuit. Areas of sunlight diffusion 10 that are illustrated with a darker shade represent regions of the standard solar panel 8a that receive relatively more sunlight radiation at this given moment. The uneven sunlight diffusion 10 is mainly determined on the basis of the particular arrangement and structure of the solar energy concentrating system 1. Having a mirror reflector 9 or any other secondary source of concentration further contributes to the uneven sunlight diffusion 10. As can be seen in FIG. 2, some solar cells 12 receive a very high amount of concentrated solar radiation, while other solar cells 12 receive very little. Since the solar cells 12 are connected in series in this standard solar module 8a, the resulting current intensity would be equal to amount of current generated by the solar cell 12 that generates the least amount of current. Considering that some of the other solar cells 12 have the potential to generate significantly more current, the resulting electrical output is inefficient.

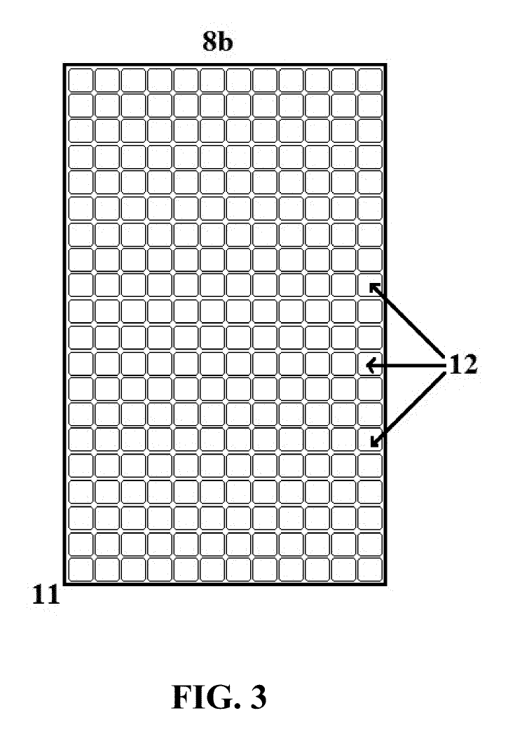

In the principal embodiment of the present invention, illustrated in FIG. 3, the solar module 8b is constituted of a very high number of solar cells 12. The solar cells 12 are distributed into multiple sets (not illustrated), each set containing a certain number of solar cells 12. In a two-part electrical circuit, solar cells 12 within each set form a parallel circuit, while the sets are connected together in series. Preferably, the solar module 8b comprises a large number of sets, and each set connects numerous solar cells 12 together. For instance, the solar module 8b can comprise twenty four sets of ten solar cells 12; in another case, the solar module 8b could comprise twenty four sets of twenty solar cells 12; and in another case, the solar module 8b could comprise twenty four sets of thirty solar cells 12. A person skilled in the art would recognize that the exact number of sets and number of solar cells 12 per set do not affect the operational structure of the present invention so long as there are numerous sets and many solar cells 12 in each set. In fact, it is not required that each set contains the same number of solar cells 12, although it is preferable in the principal embodiment of the present invention. For illustrative purposes hereinafter, the various embodiments of the present invention are described with reference to a solar module 8b constituted of twenty-four sets of ten solar cells 12.

Likewise, the optimal sizes for the solar module 8b and for the solar cells 12 would depend upon the particular solar energy system in which they are integrated. In the solar energy concentrating system 1 illustrated in FIG. 1, the optimal solar module 8b would be relatively small, so very small solar cells 12 would be required for the present embodiment to be implemented. In a larger solar energy system such as one with a tower receiver, larger modules and solar cells 12 could be used. A person skilled in the art would also recognize that the solar module 8b can take a variety of shapes, including square, circular and oval.

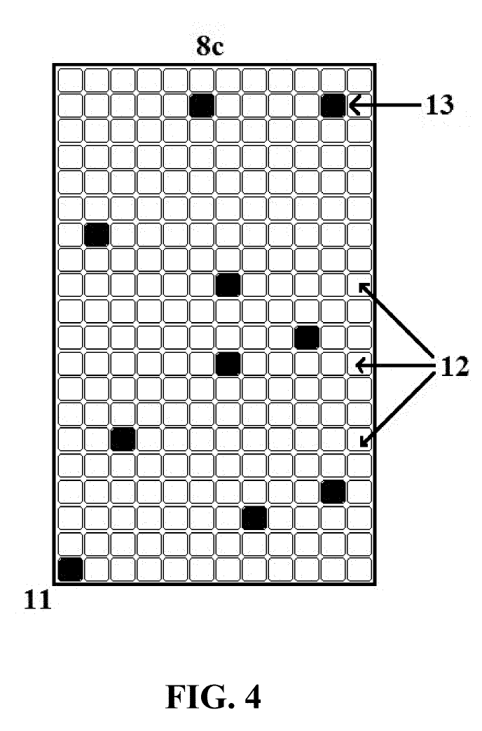

In the principal embodiment of the present invention, the solar cells 12 constituting each of the twenty-four sets are determined randomly. In FIG. 4, the solar cells 12 that are blackened represent a first set 13 that is determined randomly. With respect to the remaining other solar cells 12, this random selection is repeated for each of the twenty-three other sets of the present embodiment's solar module 8c, such that each of the solar cells 12 is included in a set.

The electrical circuit in the present invention's solar module 8c is designed in two stages. In a first stage, the ten solar cells 12 constituting a given set form a parallel circuit: this way, the current that is generated by each of the solar cells 12 within a set is added up together, ensuring that the current intensity obtained for the set is at its full potential. When the solar cells 12 constituting each of the sets are numerous and randomly selected as is the case with the present embodiment, it is very probable statistically, in accordance with the central limit theorem, that the average current intensity generated by each of the sets is more or less the same. In other words, when the solar module 8c is operated, the set that generates the most current is unlikely to produce a lot more than the set that generates the least current. As the number of solar cells 12 per set increases, the expected variance between sets decreases, meaning that the likelihood of substantial differences between set outputs of current intensity decreases as the number of solar cells 12 per set increases.

In the second stage of the electrical circuit, the twenty-four sets are connected together in series, thereby increasing the voltage of the electrical circuit of the solar module 8c. Since the current intensity of each set is very likely to be similar to one another, the probability of current intensity inefficiencies in the second stage of the electrical circuit is small. Compared with a standard solar module 8a integrated to a solar energy concentrating system, the design of the present invention offers a significantly better technological performance and is more cost-efficient.

In a first alternate embodiment, the solar cells 12 constituting each of the sets are not selected randomly but instead determined on the basis of prior simulations or calculations maximizing the current output of the set that produces the least current. Calculations yielding this result are known as “maximin”. In most situations where simulations or calculations are achieved this way, they would require being adapted to the particular solar energy concentrating system into which the solar module 8b is integrated. For instance, environmental simulations with the solar module 8b may be necessary in order to accurately assess which areas of the solar module 8b tend to receive relatively more concentrated solar radiation than others once in operation. The simulations or calculations can also be achieved during operation, with the sets being mechanically or electronically re-configured mid-operation. Although the present embodiment is likely to offer a better performance than the principal embodiment, it is also more complex as its performance is dependent upon customization with the related solar energy system and with the location where the solar module 8b would be used. In this first alternate embodiment, the two-stage electrical circuitry within and between the sets is the same as in the principal embodiment.

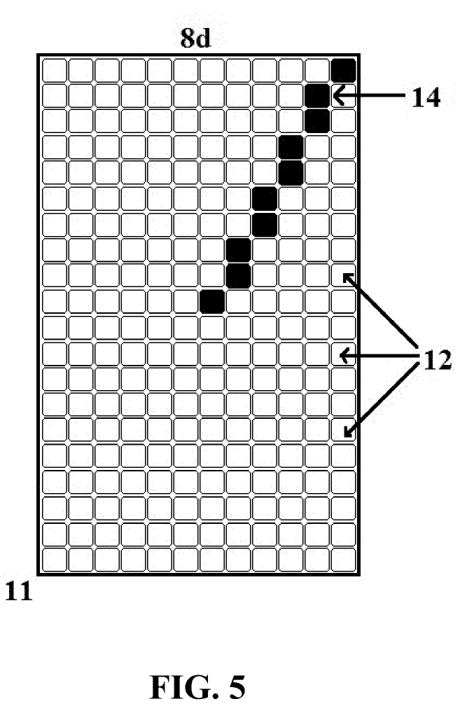

In a second alternate embodiment, illustrated in FIG. 5, the solar cells 12 constituting each of the sets are selected radially instead of being randomly determined. In this configuration, each set of the solar module 8d follows a radial pattern, diverging or radiating in line from the center of the solar module 8d. In FIG. 5, the solar cells 12 that are blackened represent a first set 14 selected in this way. A solar energy concentrating system can be operated in a way that aligns the center of the solar module 8d with the center of the target area of redirected solar radiation. In these circumstances, the current intensity of the various sets designed radially is very likely to be roughly the same. In many cases, the output generated by the radial configuration of this second alternate embodiment would be higher than the output generated by the random configuration of the principal embodiment. In this second alternate embodiment, the two-stage electrical circuitry within and between the sets is the same as in the principal embodiment.

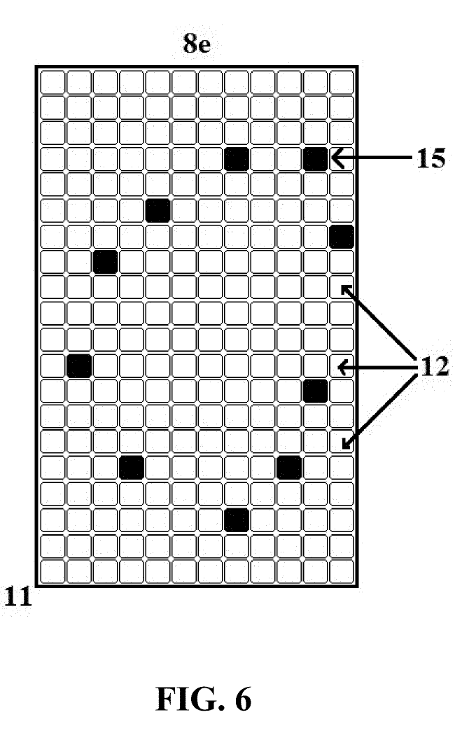

In a third alternate embodiment, illustrated in FIG. 6, the solar cells 12 constituting each of the sets are selected circularly instead of being randomly determined. In this configuration, each set of the solar module 8e follows a curve pattern—such as a circle, an oval, a spiral or a helix, or an arc of any of the foregoing—designed around the center of the solar module 8e. Preferably, the solar cells 12 constituting each set are not adjacent to one another. In FIG. 6, the solar cells 12 that are blackened represent one set 15 selected in this way. As the solar cells 12 constituting each set are widely distributed across the surface of the solar module 8e when they are not adjacent, the expected output obtained with this embodiment can be somewhat similar to the expected output of the principal embodiment whereby sets are determined randomly. In this third alternate embodiment, the two-stage electrical circuitry within and between the sets is the same as in the principal embodiment.

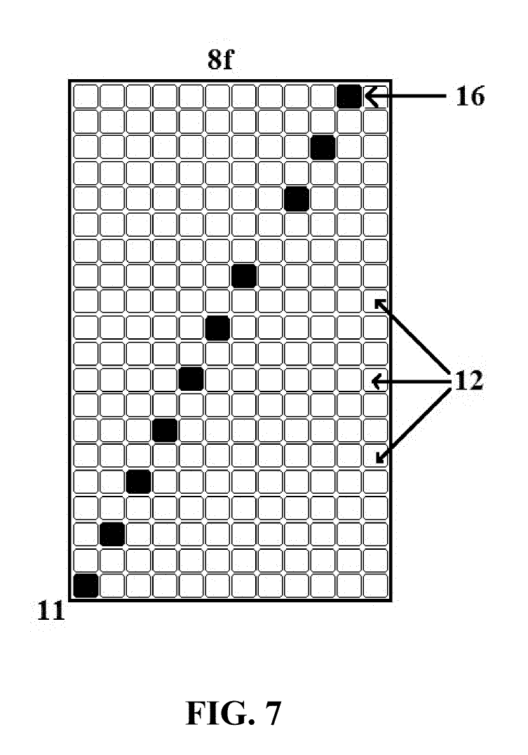

In a fourth alternate embodiment, illustrated in FIG. 7, the solar cells 12 constituting each of the sets are selected linearly instead of being randomly determined. In this configuration, each set of the solar module 8f follows a roughly linear pattern passing by or near the center of the solar module 8f. Preferably, the solar cells 12 constituting each set are not adjacent to one another. In FIG. 7, the solar cells 12 that are blackened represent one set 16 selected in this way. A solar energy concentrating system can be operated in a way that aligns the center of the solar module 8f with the center of the target area of redirected solar radiation. In these circumstances, the current intensity of the various sets designed linearly is very likely to be roughly the same. In many cases, the output generated by the linear configuration of this fourth alternate embodiment would be higher than the output generated by the random configuration of the principal embodiment. In this fourth alternate embodiment, the two-stage electrical circuitry within and between the sets is the same as in the principal embodiment.

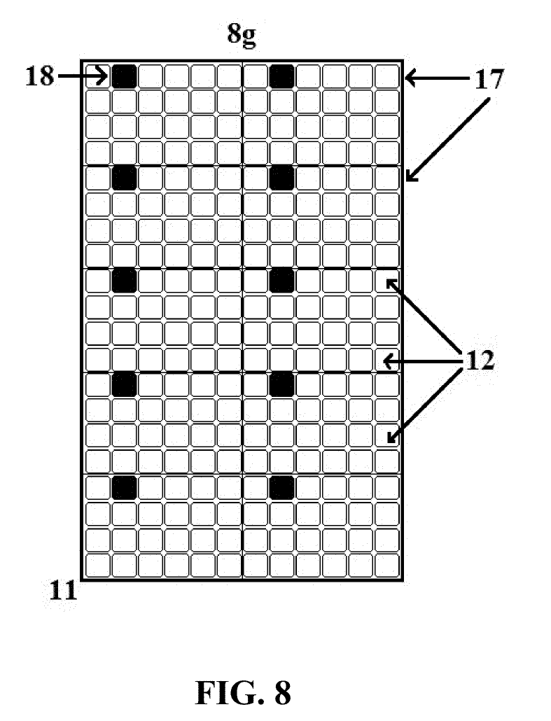

In a fifth alternate embodiment, illustrated in FIG. 8, the solar module 8g is constituted of many sections or sub-modules 17 (for instance, ten sub-modules 17 in FIG. 8). In this embodiment, the solar cells constituting each of the sets are selected on the basis of their position in each sub-module 17 instead of being randomly determined. In FIG. 8, the solar cells 12 that are blackened represent one set 18 selected in this way, where the upper, second-from-the-left solar cell 12 of each sub-module 17 are connected together to form one set. This embodiment also allows for a set to include more than one solar cell 12 per sub-module 17. As the solar cells 12 constituting each set are widely distributed across the surface of the solar module 8g, the expected output obtained with this embodiment can be somewhat similar to the expected output of the principal embodiment whereby sets are determined randomly. Since each solar cell 12 is connected to the other solar cells 12 having a same position in a sub-module 17, sub-module designs can be standardized, which in turn simplifies and lowers the costs of large-scale manufacturing and assembly of solar modules 8g. In this fifth alternate embodiment, the two-stage electrical circuitry within and between the sets is the same as in the principal embodiment.

### Additional Embodiment—Reinforced Solder Lines

Standard solar cells are designed to be oriented directly toward the sun and convert the resulting energy output into electricity. In an electrical circuit formed by a solar module constituted of standard solar cells that are concatenated, the energy is conducted to, and from, a convertor or inverter through conductors at the solar cells (which can comprise electrical contacts, metal contacts, conductive lines or any similar conductive element). When a solar cell receives concentrated solar radiation, the amount of energy that is generated is significantly higher than the amount otherwise generated when the solar cell is oriented toward the sun—for instance, potentially more than thirty suns with the solar energy concentrating system 1 described above. However, the conductors in a standard solar cell are not designed to conduct such a high amount of energy, causing a lot of resistance that reduces the efficiency of a solar energy concentrating system. To reduce the resistance directly at the solar cell's circuitry, some designs integrate wider and thicker conductors, but the dimensions of a solar cell impose inherent constraints to the width and thickness of conductors on a solar cell. Because of those constraints, even known-in-the-art designs with wider or thicker conductors on the solar cell are insufficient to efficiently conduct energy produced by a solar energy concentrator system.

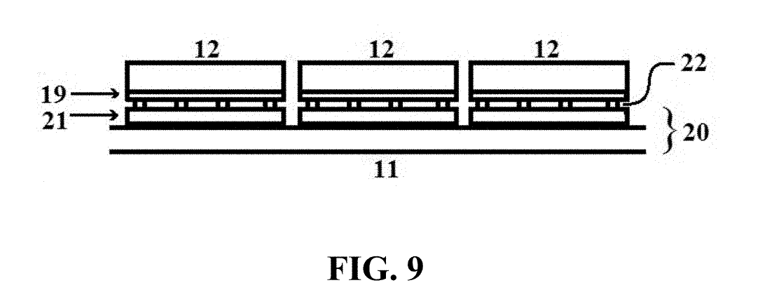

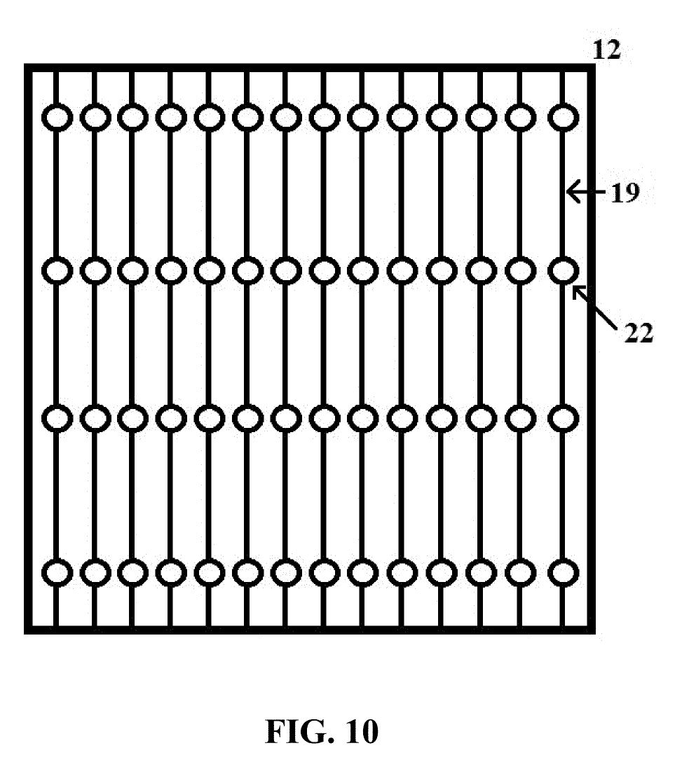

The present additional embodiment discloses a technical solution that circumvents the physical limitations of solar cells and successfully reinforces these conductors. With this embodiment, the resistance of the circuit is significantly reduced even when the solar cell receives concentrated solar radiation up to thirty suns or more. In this additional embodiment of the present invention, illustrated in FIGS. 9, 10 & 11, solar cells 12 are connected in an electrical circuit. The solar cells 12 can be standard solar cells so long as they are designed in a way that their electrical contacts and other conductive elements are positioned on their back sides, whereon conductors with relatively high resistance 19 are located. These conductors with relatively high resistance 19 can take the form of electrical tracks, traces, finger and bus bar electrodes, and so forth. The solar cells 12 are installed on a printed circuit board 20 or any other equivalent support. Together, the solar cells 12 and the printed circuit board 20 are sufficient to constitute a solar module. The printed circuit board 20 comprises a substrate 11 and conductors with relatively low resistance 21, which are typically thicker or wider (or both) than the conductors with relatively high resistance 19 on the solar cells 12. In one embodiment, in addition to, or in substitution of, the conductors with relatively low resistance 21 on the printed circuit board 20 being thicker or wider (or both) than the conductors with relatively high resistance 19 on the solar cells 12, the conductors with relatively low resistance 21 are made of materials having a better conductivity, such as superconductive materials, than the conductors with relatively high resistance 19. A person skilled in the art would recognize that equivalent means or designs exist for the conductors with relatively low resistance 21 on the printed circuit board 20 to have a relatively lower resistance than the conductors with relatively high resistance 19 on the solar cells 12.

The conductors with relatively high resistance 19 on the solar cells 12 are coupled to the conductors with relatively low resistance 21 on the printed circuit board 20 through one of various means, for instance, solder balls 22. A person skilled in the art would recognize that equivalent coupling means can be used instead of solder balls 22, such as coined solder balls, solder pads, solder bumps, metal eyelets, a ball grid array, and so forth. A person skilled in the art would also recognize that the number, location, size and pattern of the solder balls 22 or equivalent coupling means can vary, so long as they produce a conductive connection or coupling between the conductors with relatively high resistance 19 on the solar cells 12 and the conductors with relatively low resistance 21 on the printed circuit board 20. A person skilled in the art would further recognize that, so long as they are conductive, there could be more than one coupling component between the conductors with relatively high resistance 19 on the solar cells 12 and the conductors with relatively low resistance 21 on the printed circuit board 20. In one embodiment, the conductors with relatively high resistance 19 on the solar cells 12 are coupled to the conductors with relatively low resistance 21 on the printed circuit board 20 through solder lines that are each adjacent to segments—or all—of both a conductor with relatively high resistance 19 on the solar cells 12 and to a conductor with relatively low resistance 21 on the printed circuit board 20.

FIG. 9 illustrates the present embodiment with a sectional view from a side angle. FIGS. 10 & 11 illustrate the same from a bottom and a top angle, respectively, both with a view sectioned at the level of the solder balls 22. The solar cells 12 are connected to the printed circuit board 20 through the solder balls 22 and, as is visible on FIGS. 10 & 11, both ends of the solder balls 22 are respectively aligned with the conductors with relatively high resistance 19 on the solar cells 12 and the conductors with relatively low resistance 21 on the printed circuit board 20. Therefore, the conductors with relatively low resistance 21 on the printed circuit board 20 are aligned with the conductors with relatively high resistance 19 on the solar cells 12.

When solar radiation impinges on the solar cells 12, the charge carriers—electrons and holes—are knocked off their atomic bonds and are free to circulate. Circulating electrons are collected by the conductors with relatively high resistance 19 on the solar cells 12. When electrons are conducted up to a solder ball 22, they then flow, through this conductive solder ball 22, toward the conductors with relatively low resistance 21 on the printed circuit board 20. The conductors with relatively low resistance 21 on the printed circuit board 20 thereafter bring the electrons to an electrical circuit (not shown) that is external to the solar cells 12. Within this circuit, they can be used as current for electrical purposes before being brought back in a similar way to the solar cells 12, where they can fall back into empty holes.

This exemplary structure reinforces the conductors 19 on the solar cells 12 and reduces the electrical resistance of the circuit in two ways. First, the electrons travel only a small distance in the conductors with relatively high resistance 19 on the solar cells 12 before moving, through a solder ball 22, in the conductors with relatively low resistance 21 on the printed circuit board 20. As a result, even if the solar cells 12 were to be designed as a series circuit, the conductors with relatively high resistance 19 on the solar cells 12 would only carry current for their respective solar cells 12 (except for the possibility of electrons circulating incidentally). Second, for the most part, the current flows through the conductors with relatively low resistance 21 rather than through the conductors with higher resistance 19, thereby considerably reducing the circuit's resistance in comparison with a circuit entirely designed on the solar cells 12.

The present additional embodiment increases the efficiency of a solar energy concentrator system by itself. Yet, its efficiency benefits accrue even more when in combination with the principal embodiment of the present invention, because reducing the resistance of the electrical circuit overcomes an important obstacle to an efficient implementation of the principal embodiment. A person skilled in the art would recognize that the present additional embodiment can be combined with a variety of solar cells or solar modules and does not need to be combined with the principal embodiment of this invention. In addition, the present additional embodiment can be integrated into concentrating as well as non-concentrating solar energy systems.

While this invention has been particularly shown and described with reference to exemplary embodiments, it will be understood by those skilled in the art that various additions and changes in form and detail may be made therein without departing from the spirit and scope of the invention. The invention in its broadest, and more specific aspects, is further described and defined in the claims which now follow.

I claim:

1. A photovoltaic device comprising a plurality of solar cells configured to receive solar radiation and to generate an electric current output during operation, wherein the plurality of solar cells are distributed into a plurality of sets connected together in series, and wherein each of the sets comprises at least two solar cells connected together in parallel.

2. The photovoltaic device as claimed in claim 1, wherein the plurality of solar cells are distributed into the plurality of sets such that the electric current output configured to be generated during operation is substantially the same for each of the sets.

3. The photovoltaic device as claimed in claim 1, wherein the electric current output configured to be generated during operation is substantially the same for each of the sets.

4. The photovoltaic device as claimed in claim 3, wherein the plurality of cells are coupled to a same substrate.

5. The photovoltaic device as claimed in claim 3, wherein each set of the plurality of sets comprises an identical number of solar cells.

6. The photovoltaic device as claimed in claim 3, wherein the plurality of solar cells are randomly distributed into the plurality of sets.

7. The photovoltaic device as claimed in claim 6, wherein each set of the plurality of sets comprises at least ten solar cells connected together in parallel.

8. The photovoltaic device as claimed in claim 3, wherein the plurality of solar cells are distributed into the plurality of sets such that the electric current output configured to be generated during operation for the set that generates the lowest electric current output is maximized.

9. The photovoltaic device as claimed in claim 3, wherein, for each of the sets, the at least two solar cells comprised in a same set are distributed along a radial line diverging from a center area of the photovoltaic device.

10. The photovoltaic device as claimed in claim 3, wherein, for each of the sets, the at least two solar cells comprised in a same set are distributed along a curved line.

11. The photovoltaic device as claimed in claim 10, wherein, for each of the sets, the at least two solar cells comprised in a same set are nonadjacent to one another.

12. The photovoltaic device as claimed in claim 3, wherein, for each of the sets, the at least two solar cells comprised in a same set are distributed along a straight line.

13. The photovoltaic device as claimed in claim 12, wherein, for each of the sets, the at least two solar cells comprised in a same set are nonadjacent to one another.

14. The photovoltaic device as claimed in claim 3, wherein the photovoltaic device is subdivided into sections, and wherein, for each of the sets, the at least two solar cells comprised in a same set comprise solar cells positioned at a same respective area in each of the sections.

15. The photovoltaic device as claimed in claim 3, wherein the photovoltaic device further comprises a printed circuit board comprising conductors electrically coupled to conductors on back sides of the plurality of solar cells.

16. The photovoltaic device as claimed in claim 15, wherein the conductors comprised in the printed circuit board have a lower resistance than the conductors on the back sides of the plurality of solar cells.

17. The photovoltaic device as claimed in claim 3, wherein the photovoltaic device is comprised in a solar energy concentrator system.

18. A photovoltaic device comprising a plurality of solar cells having front sides configured to receive solar radiation and to generate an electric current output during operation and back sides opposite the front sides, wherein the photovoltaic device further comprises a printed circuit board comprising conductors electrically coupled to conductors on the back sides of the plurality of solar cells.

19. The photovoltaic device as claimed in claim 18, wherein the conductors comprised in the printed circuit board have a lower resistance than the conductors on the back sides of the plurality of solar cells.

20. The photovoltaic device as claimed in claim 19, wherein the photovoltaic device is comprised in a solar energy concentrator system.
